(19) United States
(12) Patent Application Publication
(10) Pub. No.: US 2009/0250817 A1
(43) Pub. Date: Oct. 8, 2009

(54) METHOD OF FABRICATING SEMICONDUCTOR DEVICE AND SEMICONDUCTOR DEVICE

(76) Inventor: Hiroyuki MAEDA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/403,718

(22) Filed: Mar. 13, 2009

(30) Foreign Application Priority Data
Apr. 4, 2008 (JP) 2008-97818

(51) Int. Cl. H01L 23/52; G03F 7/20

(52) U.S. Cl. 257/751; 430/313; 257/E23.141

(57) ABSTRACT

A method of fabricating a semiconductor device according to embodiments includes forming a resist film above an object to be etched, the resist film having a pattern with notches provided in the vicinity of corners having an angle of less than 180 degrees on an opening side, and dry etching the object to be etched using the resist film as a mask, thereby transferring the pattern of the resist film.

### CROSS-REFERENCE TO RELATED APPLICATIONS

This application is based upon and claims the benefit of priority from prior Japanese Patent Application No. 2008-097818, filed on Apr. 4, 2008, the entire contents of which are incorporated herein by reference.

### BACKGROUND

In recent years, along with a miniaturization of a pattern in a semiconductor device, an OPC (Optical Proximity Correction) technique for suppressing a dimensional variation generated in a lithographic process by correcting a mask pattern, or a PPC (Process Proximity Correction) technique for suppressing a dimensional variation generated in a masking process, a lithographic process and an etching process by correcting a mask pattern, has been suggested (for example, disclosed in Japanese Patent Laid-Open (JP-A-09-319067)).

In the OPC technique, a mask pattern is corrected by, e.g., partially thickening or thinning a pattern, or arranging a pattern emphasizing corners at the corners. In the PPC technique, a mask pattern is corrected by, e.g., using a previously derived correction value corresponding to a layout of a peripheral pattern.

Meanwhile, a phenomenon in which a sidewall of a concave portion becomes an inclined surface due to an etching product during a process for forming a concave portion by dry etching (a loading effect) has been generally known.

However, it is difficult to control a shape of the concave portion with high accuracy in the OPC technique and the PPC technique, thus, further improvement is desired.

### BRIEF SUMMARY

A method of fabricating a semiconductor device according to embodiments includes forming a resist film above an object to be etched, the resist film having a pattern with notches provided in the vicinity of corners having an angle of less than 180 degrees on an opening side, and dry etching the object to be etched using the resist film as a mask, thereby transferring the pattern of the resist film.

The semiconductor device according to the embodiments includes a pattern film formed by dry etching a concave portion and notches provided in the vicinity of corners having an angle of less than 180 degrees on an opening side of the concave portion, and an embedding material embedded into the concave portion and the notches.

### BRIEF DESCRIPTION OF THE DRAWING

FIGS. 1A and 1B are diagrams showing a schematic configuration of a photomask according to a first embodiment, wherein FIG. 1A is a front view and FIG. 1B is a plane view;

FIGS. 2A to 2C are diagrams showing etching processes using a photomask;

FIG. 3 is a plane view of FIG. 2C;

FIG. 4A is a plane view of Comparative Example 1, FIG. 4B is a cross-sectional view along line A-A of FIG. 4A and FIG. 4C is a cross-sectional view along line A-A of FIG. 4A for explaining an ion implantation process;

FIGS. 5A and 5B are diagrams showing a modification of a notch on a mask pattern;

FIG. 6 is a plane view schematically showing a photomask according to a second embodiment;

FIG. 7 is a plane view showing a resist film, an insulating film and a foundation layer after dry etching;

FIG. 8 is a cross-sectional view of a main portion showing a wiring part of a semiconductor device according to a third embodiment; and

FIG. 9 is a cross-sectional view of a main portion showing Comparative Example 2 corresponding to the third embodiment.

### DETAILED DESCRIPTION

### First Embodiment

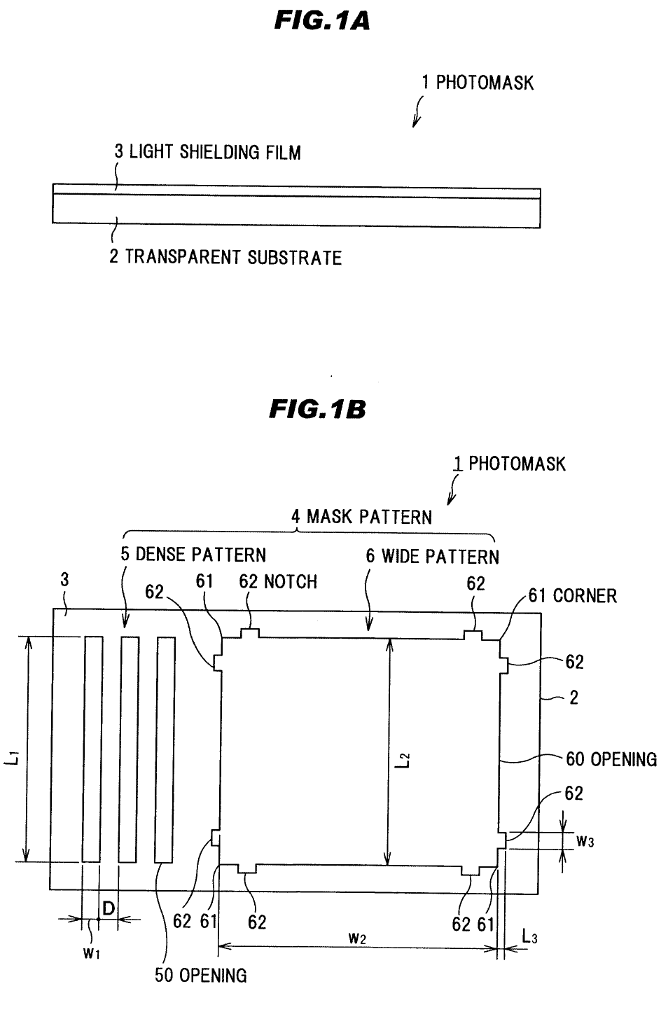

A method of fabricating a semiconductor device according to the first embodiment will be described with reference to FIGS. 1A, 1B, 2A to 2C, 3 and 4A to 4C.

### (1) Formation of a Photomask

FIGS. 1A and 1B are diagrams showing a schematic configuration of a photomask according to a first embodiment, wherein FIG. 1A is a front view and FIG. 1B is a plane view.

As shown in FIG. 1A, a photomask 1 includes a transparent substrate 2 formed of silica glass, etc., and a light shielding film 3 formed of a metal such as chrome, etc., formed on one side of the transparent substrate 2. Note that, this embodiment is not limited thereto, and for example, it may be a phase shift mask, etc., further provided with a semitransparent film.

As shown in FIG. 1B, a mask pattern 4 is formed on the light shielding film 3. The mask pattern 4 includes a dense pattern 5 composed of plural dense openings 50 of which opening width W, and distance between the openings D are small, and a wide pattern 6 composed of an opening 60 having an opening width W₂ which is larger than the opening width W₁ of the opening 50 of the dense pattern 5.

The opening 50 of the dense pattern 5 has, e.g., a linear shape with the opening width W₁ and a length L₁ (L₁>W₁). As a specific example, W₁=0.55 μm, L₁=5.5 μm and D=0.55 μm.

The opening 60 of the wide pattern 6 has, e.g., a rectangular shape with the opening width W₂ and a length L₂. As a specific example, W₂=2.2 μm and L₂=5.5 μm.

In addition, in the opening 60 of the wide pattern 6, each pair of notches 62 is provided in the vicinity of four corners 61 having an angle of less than 180 degrees on the opening 60 side so as to straddle the corner 61. Here, “the vicinity of the corner 61” means a region in which a below described excavation is more likely to be generated, for example, a portion of a side of the opening 60 up to 1 μm from the corner 61. A pair of notches 62 has a function to reduce concentration of etching species to the object to be etched in a dry etching process. The notch 62 has, e.g., a slit shape with a width W₃ and a length L₃. As a specific example, W₃=0.55 μm and L₃=0.30 μm.

For a horizontal to vertical ratio (length of long side/length of short side) of the opening 60 of the wide pattern 6, a value of 1-3, preferably 1-2, etc., may be adopted depending on the application, etc. Meanwhile, for an opening width ratio of the opening width W₂ of the wide pattern 6 to the opening width W₁ of the dense pattern 5 (W₂/W₁), a value of 3 or more, preferably 4 or more, may be adopted depending on the application, etc. For the width W₃ of the notch 62, a value of 0.1-1 μm, preferably 0.3-0.8 μm, etc., maybe adopted depending on a concentration level of the etching species, etc.

The photomask 1 configured as described above is formed through a lithographic process of forming the light shielding film 3 on one surface of the transparent substrate 2, applying an electron beam resist film on the light shielding film 3 and irradiating the electron beam on the electron beam resist film for drawing,followed by development, etching or resist removing, etc. Note that, for the drawing, an X-ray, a laser beam or the like may be used other than the electron beam.

### (2) Patterning Using a Photomask

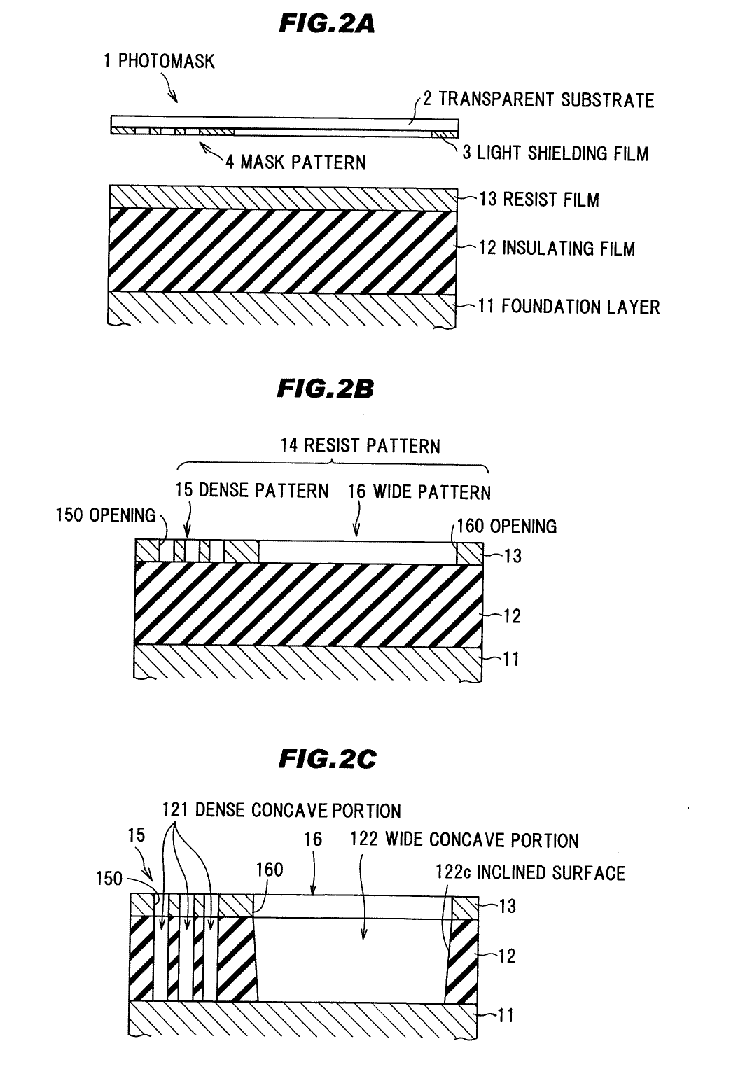

FIGS. 2A to 2C are diagrams showing etching processes using a photomask 1. In the embodiment, the case where an insulating film 12 as a pattern film formed on a foundation layer 11 composed of a semiconductor material, etc., is used as an object to be etched and a concave portion is formed on the insulating film 12, will be described. Note that, an anti-etching film such as a silicon nitride film, etc., that suppresses a below-described foundation excavation due to dry etching may be formed on an upper surface of the foundation layer 11.

The insulating film 12 as an object to be etched may be formed of, e.g., a silicon compound, etc., composed of Si, SiO₂, Si₃N₄ or the like. Note that, the object to be etched may be a substrate such as a Si substrate, etc. Alternatively, a material for the object to be etched may be a semiconductor material such as GaAs or GaN, etc., or a metal such as Al or Cu, etc.

As shown in FIG. 2A, a resist film 13 is formed on the insulating film 12 and the resist film 13 is lithographically processed by irradiating exposure light such as ultraviolet light, etc., onto the resist film 13 via a mask pattern 4 of the photomask 1. As shown in FIG. 2B, the dense pattern 5 and the wide pattern 6 of the photomask 1 are transferred to the resist film 13, which results in that a resist pattern 14 composed of a dense pattern 15 and a wide pattern 16 is formed. Similarly to the wide pattern 6 of the photomask 1, the wide pattern 16 of the resist film 13 has notches in the vicinity of corners.

### (3) Dry Etching Using a Resist Film as a Mask

As shown in FIG. 2C, the insulating film 12 is dry etched using the resist film 13 with the resist pattern 14 formed thereon as a mask. In the insulating film 12, plural dense concave portions 121 are formed corresponding to the dense pattern 15 so as to have substantially vertical sidewalls, and a wide concave portion 122 is formed corresponding to the wide pattern 16 so as to have inclined sidewalls. The resist film 13 is removed after dry etching the insulating film 12. Note that, another process such as ion implantation, etc., may be inserted before removing the resist film 13.

In the embodiment, reactive dry etching is used as the dry etching. The reactive dry etching is conducted by ionizing an etching gas species (an etching species) using plasma, and irradiating the ion onto the insulating film 12. The etching gas species is selected in accordance with a material of the object to be etched. For example, when the object to be etched is SiO₂, CF-based gas such as mixed gas containing C₄F₈, Co, Ar or O₂, or mixed gas containing C₅F₈, Co, Ar or O₂ or the like is used.

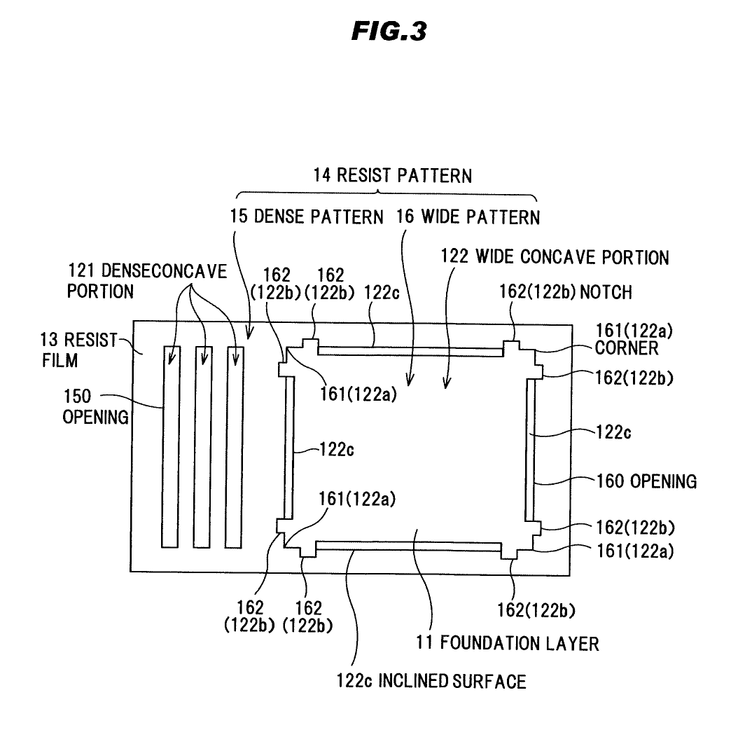

FIG. 3 is a plane view of FIG. 2C. The resist pattern 14 of the resist film 13 includes the dense pattern 15 composed of dense openings 150 and the wide pattern 16 composed of an opening 160. Notches 162 are formed in the vicinity of corners 161 of the opening 160. By the dry etching using the resist film 13, plural dense concave portions 121 and the wide concave portion 122 are formed in the insulating film 12, notches 122b are formed in the vicinity of corners 122a in the wide concave portion 122, and inclined surfaces 122c due to an etching product are formed on the sidewalls.

Subsequently, an embedding material formed of an insulating material, a semiconductor material or a conductive material, etc., is embedded into the dense concave portions 121 and the wide concave portion 122, similar processes using a second photomask are conducted if necessary, and a semiconductor device is fabricated. When the second photomask has a wide pattern similarly to the first embodiment, it is desirable to provide notches in the vicinity of corners.

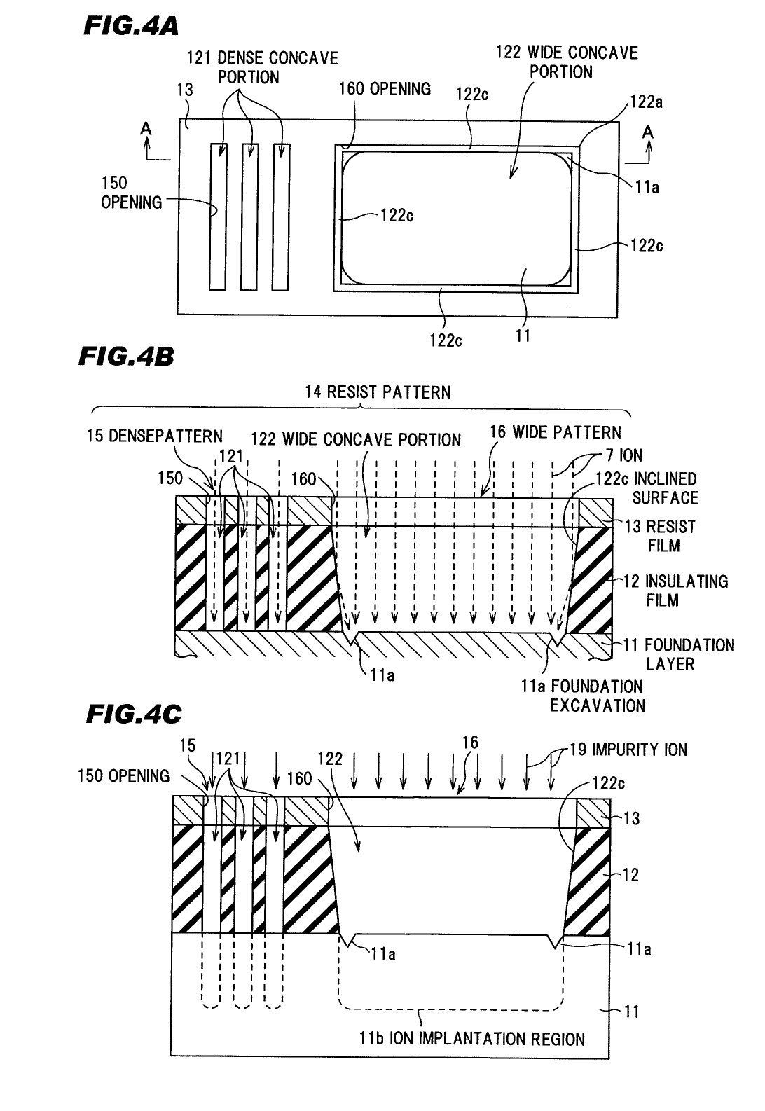

Here, FIG. 4A is a plane view of Comparative Example 1, FIG. 4B is a cross-sectional view along line A-A of FIG. 4A and FIG. 4C is a cross-sectional view along line A-A of FIG. 4A for explaining an ion implantation process. In Comparative Example 1, a photomask not provided with the notches 62 in the vicinity of the corners 61 of the opening 60 of the wide pattern 6 is used compared with the photomask 1 shown in FIGS. 1A and 1B.

The dense pattern 15 composed of the dense openings 150 and the wide pattern 16 composed of the opening 160 not having notches are patterned on the resist film 13 by exposing and developing the resist film 13 on the insulating film 12. Next, by dry etching the insulating film 12 using the resist film 13 as a mask, the plural dense concave portions 121 corresponding to the dense pattern 15 and the wide concave portion 122 corresponding to the wide pattern 16 not having notches are formed on the insulating film 12. Since the optimum etching condition for the dense pattern 15 is different from that of the wide pattern 16 and the etching gas species cannot be sufficiently supplied to the wide pattern 16 compared with the dense pattern 15, similarly to the first embodiment, the sidewalls of the wide concave portion 122 become the inclined surfaces 122c due to the etching product while the dense concave portions 121 are vertically processed.

And then, when the wide concave portion 122 is formed, since an ion 7 as an etching species reaches the foundation layer 11 by being reflected at the inclined surface 122c of the wide concave portion 122, the ion 7 reflected at the inclined surface 122c and the ion 7 substantially vertically attacking the foundation layer 11 without being reflected at the inclined surface 122c concentrate at a lower part of the inclined surface 122c, thus, it is difficult to completely suppress the generation of a foundation excavation 11a even if an anti-etching film is provided on a surface of the foundation layer 11.

As shown in FIG. 4A, since the ion 7 reaches the foundation layer 11 by being reflected at the inclined surface 122c from two directions of a vertical side and a horizontal side and concentrates, in the vicinity of the corners 122a of the wide concave portion 122 the foundation excavation 11a is particularly likely to be generated. For example, as shown in FIG. 4C, when an ion implantation region 11b is formed by implanting an impurity ion 19 into the foundation layer 11 using the resist pattern 14 as a mask in the state that the foundation excavation 11a is formed, unevenness of impurity implantation depth is generated. And, even in the case that the foundation excavation 11a is generated in a foundation substrate that is formed by preliminarily implanting the impurity, for example, if a semiconductor device is applied to a transistor, variation may be generated in operating characteristics. In addition, when repeating formation and removal of the insulating film, etc., in a posterior process after implanting the impurity ion 19 into the foundation layer 11, the insulating film, etc., entered into the foundation excavation 11a may not be removed completely.

On the other hand, according to the first embodiment, since the object to be etched is dry etched using the resist mask with notches provided in the vicinity of corners of the wide pattern as a mask, an inclined surface due to the etching product is unlikely to be formed in the vicinity of the corners of the wide concave portion. As a result, it is possible to suppress the generation of the foundation excavation described in Comparative Example 1.

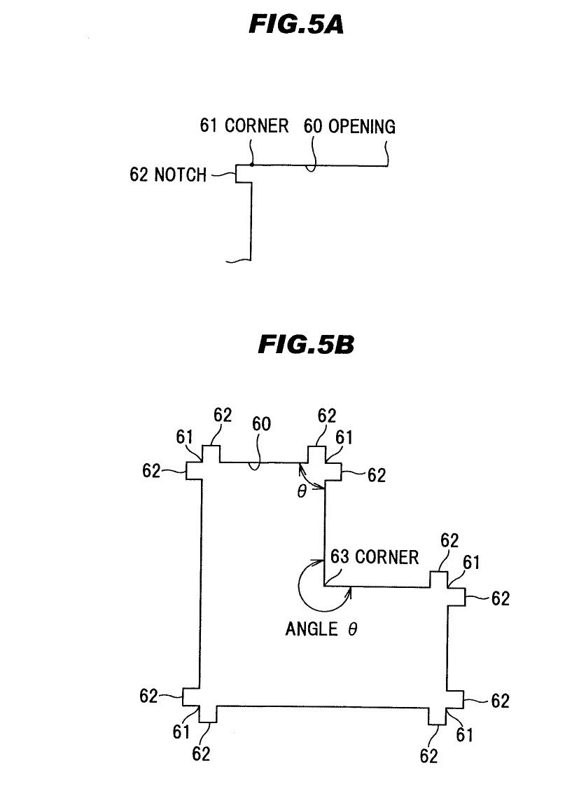

FIGS. 5A and 5B are diagrams showing a modification of a notch on a mask pattern. Depending on the concentration level of the etching species, the notches 62 may be provided on only one side of the corner 61 as shown in FIG. 5A, without providing on both sides. In addition, the opening 60 is not limited to a rectangular and it may be another shape such as an L-shape, etc., as shown in FIG. 5B. In this case, the notches 62 are provided in the vicinity of five corners 61 having an angle of less than 180 degrees on the opening 60 side, and are not provided in the vicinity of a corner 63 having an angle 0 of 180 degrees or more (270 degrees in FIG. 5B) on the opening 60 side. In addition, the notch 62 is not limited to the slit shape and it may be another shape such as semicircle, etc. Although the notch 62 is formed so as to be positioned at the corner in the modification, the notch 62 may be formed so as to provide a slight gap between it and the corner 61 within a range of 1 μm from the corner 61.

### Second Embodiment

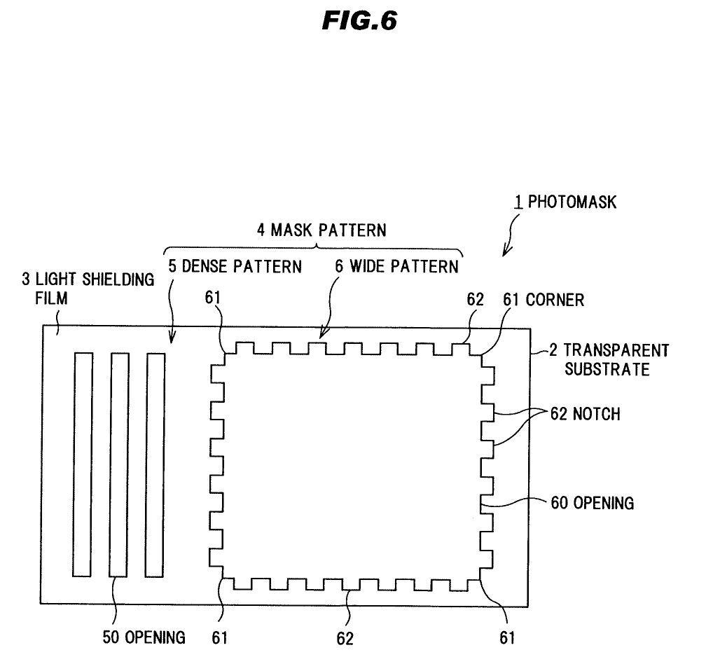

FIG. 6 is a plane view schematically showing a photomask according to a second embodiment. In the photomask 1 of the embodiment, the notches 62 are provided also on the sides forming the corners 61 compared with the photomask 1 of the first embodiment. In other words, similarly to the first embodiment, the mask pattern 4 of the photomask 1 includes the dense pattern 5 composed of the plural openings 50 and the wide pattern 6 composed of the wide opening 60, and in the opening 60, a concavo-convex pattern formed by the plural notches 62 is formed on the sides between the adjacent corners 61 including the vicinity of four corners 61.

The notch 62 is composed of a slit with a width W₃ and a length L₃, and a distance between the notches 62 is equal to, e.g., W₃.

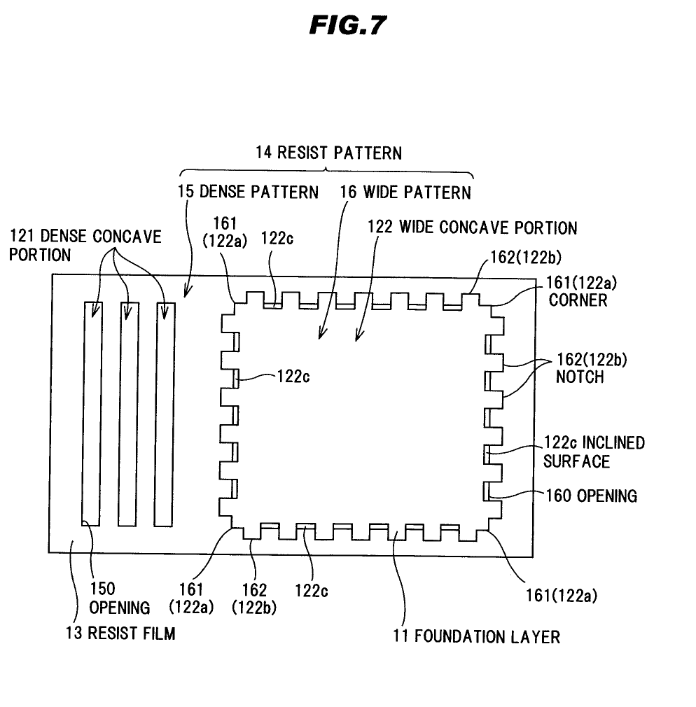

FIG. 7 is a plane view showing a resist film, an insulating film and a foundation layer after dry etching. The resist pattern 14 is transferred to the resist film 13 using the photomask 1 shown in FIG. 6, which results in that the dense pattern 15 composed of plural dense openings 150 and the wide pattern 16 composed of the opening 160 having the notches 62 in the vicinity of the corners 161 and on the sides forming the corners 161 are formed on the resist film 13, as shown in FIG. 7. When the insulating film 12 is dry etched using the resist film 13 as a mask, the wide concave portion 122 with the notches 122b formed in the vicinity of the corners 122a and on the sides forming the corners 122a is formed.

According to the second embodiment, similarly to the first embodiment, it is possible to suppress the generation of the foundation excavation. Furthermore, it is possible to decrease an inclination angle of the inclined surface 122c compared with the first embodiment.

### Third Embodiment

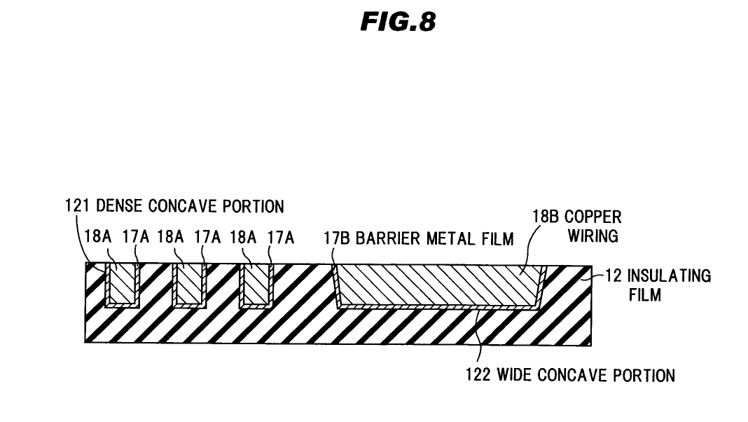

FIG. 8 is a cross-sectional view of a main portion showing a wiring part of a semiconductor device according to a third embodiment. A formation method of a wiring part of the semiconductor device according to the embodiment will be described with reference to FIG. 8.

Firstly, the mask pattern 4 of the photomask 1 is transferred to a resist film on the insulating film 12 using the photomask 1 of the first embodiment, the insulating film 12 is dry etched using the resist film as a mask, and similarly to the first embodiment, plural dense concave portions 121 and the wide concave portion 122 having notches in the vicinity of corners are formed on the insulating film 12.

Next, on the whole surface of the insulating film 12 including trenches of the dense concave portions 121 and the wide concave portion 122, barrier metal films 17A and 17B formed of Ta, Ti or a compound thereof are formed by sputtering or a CVD method for preventing copper from diffusing into the insulating film 12. And then, after Cu is formed on the whole surface of the insulating film 12 including the trenches by sputtering or plating, etc., barrier metal and Cu outside of the trenches are removed by CMP (Chemical Mechanical Polishing), thereby forming copper wirings 18A and 18B.

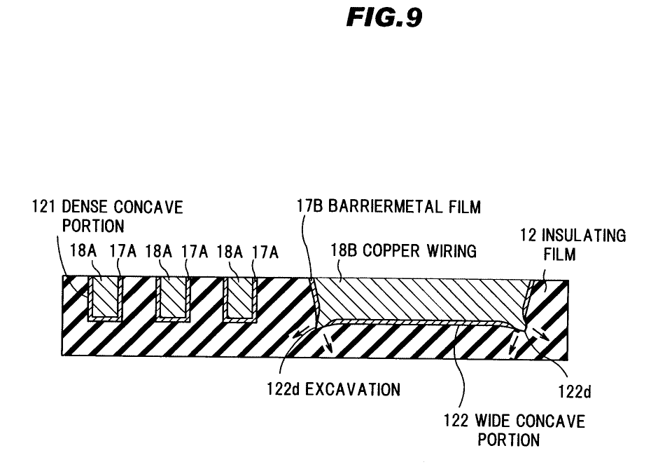

Here, FIG. 9 is a cross-sectional view of a main portion showing Comparative Example 2 corresponding to the third embodiment. In Comparative Example 2, a photomask not provided with the notches 62 in the vicinity of the corners 61 of the opening 60 is used compared with the photomask 1 shown in FIGS. 1A and 1B. If the dense concave portions 121 and the wide concave portion 122 are formed on the insulating film 12 using the photomask not provided with the notches, excavations 122d are generated at lower portions of four corners of the wide concave portion 122, consequently the barrier metal film 17B is discontinued at the lower portion of the four corners of the wide concave portion 122, and Cu in the copper wiring 18B may possibly diffuse into the insulating film 12 from the portion where the barrier metal film 17B is discontinued.

On the other hand, according to the third embodiment, since concave portions with no excavation are formed by dry etching the insulating film using the resist mask with notches provided in the vicinity of corners of the wire pattern as a mask and the barrier metal films 17A and 17B are formed in these concave portions, the barrier metal film 17B is not discontinued unlike Comparative Example 2 and it is possible to suppress the diffusion of Cu in the copper wiring 18B into the insulating film 12.

Note that, similarly to the second embodiment, a photomask having plural notches also on sides of the wide pattern may be used for forming the wiring part.

It should be noted that the present invention is not intended to be limited to the above-mentioned first to third embodiments, and various kinds of changes thereof can be implemented by those skilled in the art without departing from the gist of the invention.

For example, although a photmask is used in the above-mentioned each embodiment, an electron beam lithography process for directly drawing on a resist film without using a photomask may be adopted.

What is claimed is:

1. A method of fabricating a semiconductor device comprising :
forming a resist film above an object to be etched, the resist film having a pattern with notches provided in the vicinity of corners having an angle of less than 180 degrees on an opening side; and
dry etching the object to be etched using the resist film as a mask, thereby transferring the pattern of the resist film.

2. A method of fabricating a semiconductor device according to claim 1, wherein forming the resist film above the object to be etched comprises forming the resist film having a pattern with the notches provided in the vicinity of the corners having an angle of less than 180 degrees on the opening side as well as with a plurality of notches provided on sides forming at least one of the corners having angle of less than 180 degrees on the opening side.

3. The method of fabricating a semiconductor device according to claim 1, wherein the notches include a pair of notches formed so as to straddle at least one of the corners.

4. The method of fabricating a semiconductor device according to claim 1, wherein the notches have a width of 0.1-1 μm.

5. The method of fabricating a semiconductor device according to claim 1, wherein the notches are formed within a range of 1 μm from the corners.

6. The method of fabricating a semiconductor device according to claim 1, wherein the object to be etched is an insulating film.

7. The method of fabricating a semiconductor device according to claim 6, wherein the insulating film is formed on a foundation layer via an anti-etching film.

8. The method of fabricating a semiconductor device according to claim 1, wherein dry etching the object to be etched using the resist film as the mask comprises forming on opening with an inclined sidewall on the object to be etched.

9. A method of fabricating a semiconductor device comprising :
forming a resist film above an object to be etched, the resist film having a dense pattern comprising a plurality of dense openings with a small opening width and a wide pattern comprising an opening with an opening width larger than that of the dense pattern, and being provided with notches in the vicinity of corners having an angle of less than 180 degrees on an opening side of the wide pattern; and
dry etching the object to be etched using the resist film as a mask, thereby transferring the dense pattern and the wide pattern of the resist film.

10. The method of fabricating a semiconductor device according to claim 9, wherein forming the resist film above the object to be etched comprises forming the resist film having a pattern with the notches provided in the vicinity of the corners having an angle of less than 180 degrees on the opening side as well as with a plurality of notches provided on sides forming at least one of the corners having angle of less than 180 degrees on the opening side.

11. The method of fabricating a semiconductor device according to claim 9, wherein an opening width of the wide pattern has a dimension three times or more larger than that of the dense pattern.

12. The method of fabricating a semiconductor device according to claim 9, wherein the notches include a pair of notches formed so as to straddle at least one of the corners.

13. The method of fabricating a semiconductor device according to claim 9, wherein the notches have a width of 0.1-1 μm.

14. The method of fabricating a semiconductor device according to claim 9, wherein the notches are formed within a range of 1 μm from the corners.

15. The method of fabricating a semiconductor device according to claim 9, wherein the object to be etched is an insulating film.

16. The method of fabricating a semiconductor device according to claim 15, wherein the insulating film is formed on a foundation layer via an anti-etching film.

17. The method of fabricating a semiconductor device according to claim 9, wherein dry etching the object to be etched using the resist film as the mask comprises forming an opening with an inclined sidewall on the object to be etched, thereby transforming the wide pattern of the resist film.

18. The method of fabricating a semiconductor device according to claim 9, wherein dry etching the object to be etched using the resist film as the mask comprises forming a plurality of openings with substantially vertical sidewalls on the object to be etched, thereby transforming the dense pattern of the resist film.

19. A semiconductor device, comprising:
a pattern film in which a concave portion and notches provided in the vicinity of corners having an angle of less than 180 degrees on an opening side of the concave portion are formed by dry etching; and
an embedding material embedded into the concave portion and the notches.

20. The semiconductor device according to claim 19, wherein the pattern film is an insulating film; and
the embedding material is copper embedded into the insulating film via a barrier metal film.
